(19) United States
(12) Patent Application Publication
(10) Pub. No.: US 2026/0052958 A1
(43) Pub. Date: Feb. 19, 2026

(54) SEMICONDUCTOR DEVICE STRUCTURE AND METHOD FOR FORMING THE SAME

(71) Applicant: Taiwan Semiconductor Manufacturing Company, Ltd., Hsinchu (TW)

(72) Inventor: Chih-Yang CHEN, Hsinchu City (TW)

(73) Assignee: Taiwan Semiconductor Manufacturing Company, Ltd., Hsinchu (TW)

(21) Appl. No.: 18/808,655

(22) Filed: Aug. 19, 2024

(51) Int. Cl. H01L 21/762; H01L 21/8234; H01L 27/088; H01L 29/06; H01L 29/423; H01L 29/66; H01L 29/775; H01L 29/786

(52) U.S. Cl. CPC H01L 21/76229; H10D 84/0151; H10D 84/038; H10D 84/83; H10D 30/014; H10D 30/43; H10D 30/6735; H10D 30/6757; H10D 62/121; H10D 64/017

(57) ABSTRACT

A method for forming a semiconductor device structure includes forming fin base structures over a first region and a second region of a substrate and channel layers over the fin base structures. The distances between the fin structures in the first region and the second region are different. The method also includes filling an isolation material between the fin base structures and recessing the isolation material to form a first isolation structure in the first region and a second isolation structure in the second region. The method also includes depositing a hard mask layer over the first isolation structure and the second isolation structure. The thicknesses of the hard mask layer in the first region and the second region are different, and the top surfaces of the hard mask layer in the first region and the second region are substantially at the same level.

### BACKGROUND

Semiconductor devices are used in a variety of electronic applications, such as personal computers, cell phones, digital cameras, and other electronic equipment. Semiconductor devices are typically fabricated by sequentially depositing insulating or ILD structures, conductive layers, and semiconductive layers of material over a semiconductor substrate, and patterning the various material layers using lithography to form circuit components and elements thereon. Many integrated circuits are typically manufactured on a single semiconductor wafer, and individual dies on the wafer are singulated by sawing between the integrated circuits along a scribe line. The individual dies are typically packaged separately, in multi-chip modules, for example, or in other types of packaging.

Recently, multi-gate devices have been introduced in an effort to improve gate control by increasing gate-channel coupling, reduce OFF-state current, and reduce short-channel effects (SCEs). One such multi-gate device that has been introduced is the gate-all around transistor (GAA). The GAA device gets its name from the gate structure which can extend around the channel region providing access to the channel on two or four sides. GAA devices are compatible with conventional complementary metal-oxide-semiconductor (CMOS) processes.

However, the integration of fabrication of the GAA features around the nanowire can be challenging. While the current methods have been satisfactory in many respects, continued improvements are still needed.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1A-1C, 1D, 1E, 1F, 1G, 1H are perspective representations of various stages of forming a semiconductor device structure, in accordance with some embodiments of the disclosure.

FIGS. 1C-1, 1D-1, 1E-1, 1F-1, 1G-1, 1H-1 are cross-sectional representations of various stages of forming a semiconductor device structure, in accordance with some embodiments of the disclosure.

FIG. 2 is a cross-sectional representation of a semiconductor device structure, in accordance with some embodiments of the disclosure.

FIG. 3 is a cross-sectional representation of a semiconductor device structure, in accordance with some embodiments of the disclosure.

FIG. 4 is a cross-sectional representation of a semiconductor device structure, in accordance with some embodiments of the disclosure.

FIG. 5 is a cross-sectional representation of a semiconductor device structure, in accordance with some embodiments of the disclosure.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numbers are used to designate like elements. It should be understood that additional operations can be provided before, during, and after the method, and some of the operations described can be replaced or eliminated for other embodiments of the method.

The nanostructure transistor (e.g. nanosheet transistor, nanowire transistor, multi-bridge channel, nano-ribbon FET, forksheet structures, gate all around (GAA) transistor structures) described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the nanostructures.

Embodiments for forming a semiconductor device structure are provided. The method for forming the semiconductor device structure may include forming isolation structures with different widths and heights in different regions of a substrate. The loading effect of the hard mask layer formed over the isolation structures may be compensated, and the capacitance uniformity may be improved.

The semiconductor device structure may include various active devices. For example, the semiconductor device structure may include gate all around (GAA) structures. The semiconductor device structure may also include channel structures such as nanosheet structures, forksheet structures, and CFET structures. The semiconductor device structure may also include FinFET structures, or Si and SiGe planar transistors.

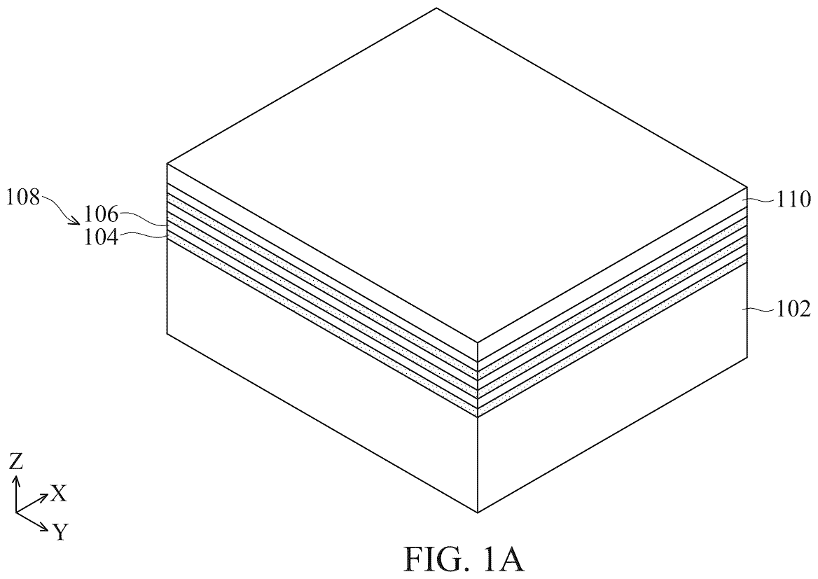

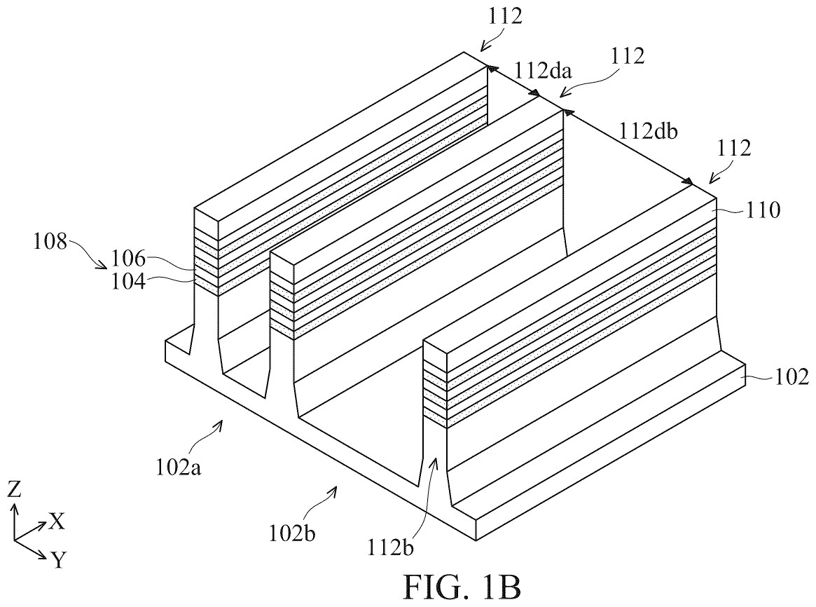

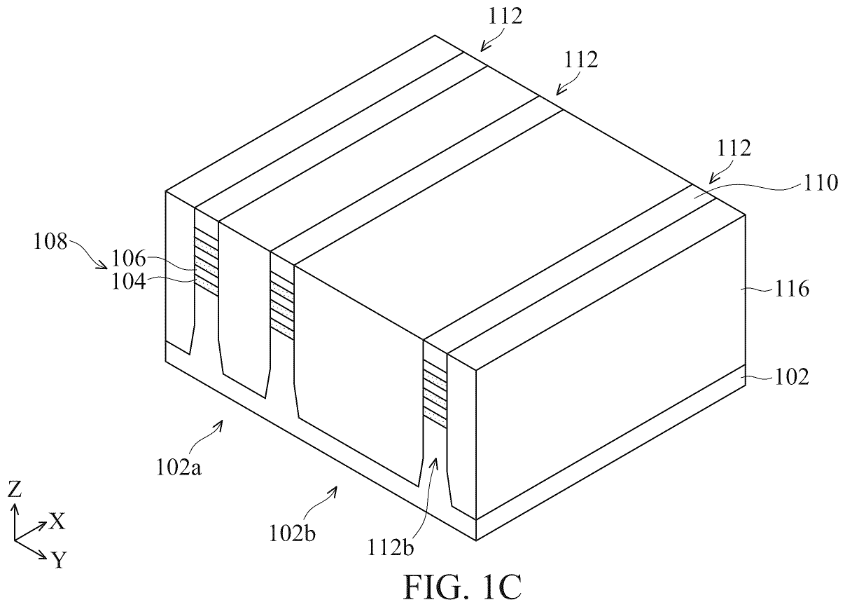

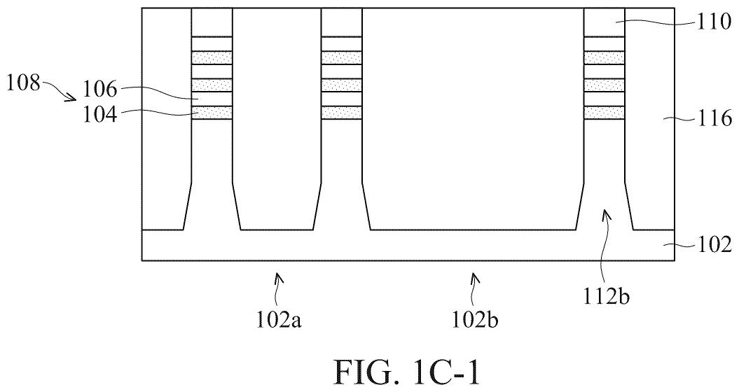

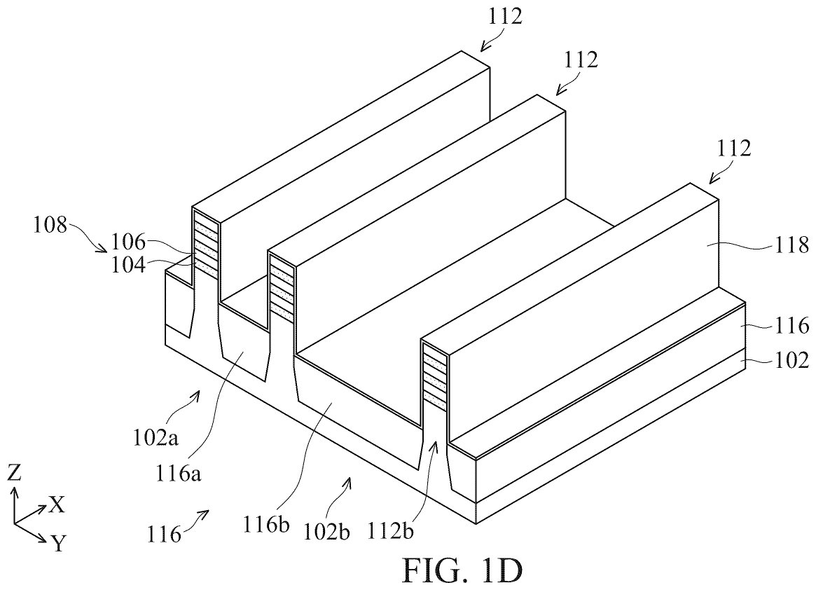

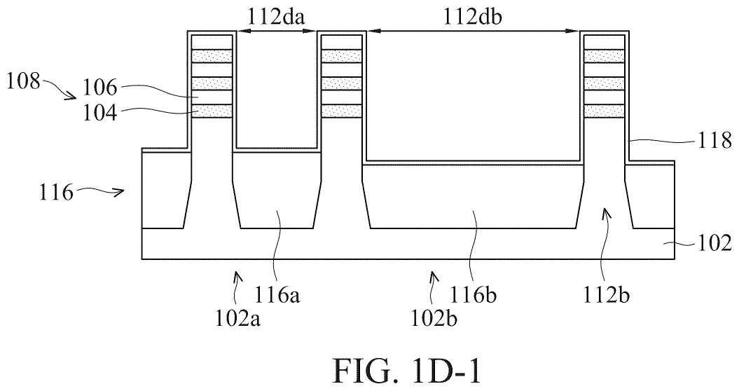

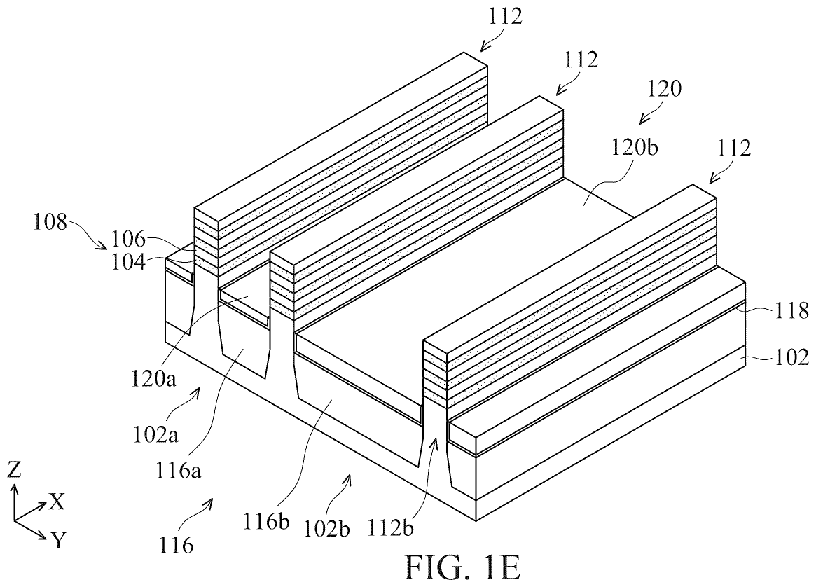

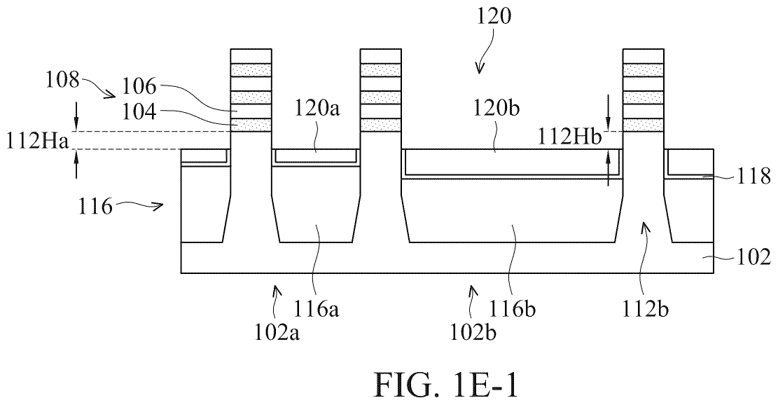

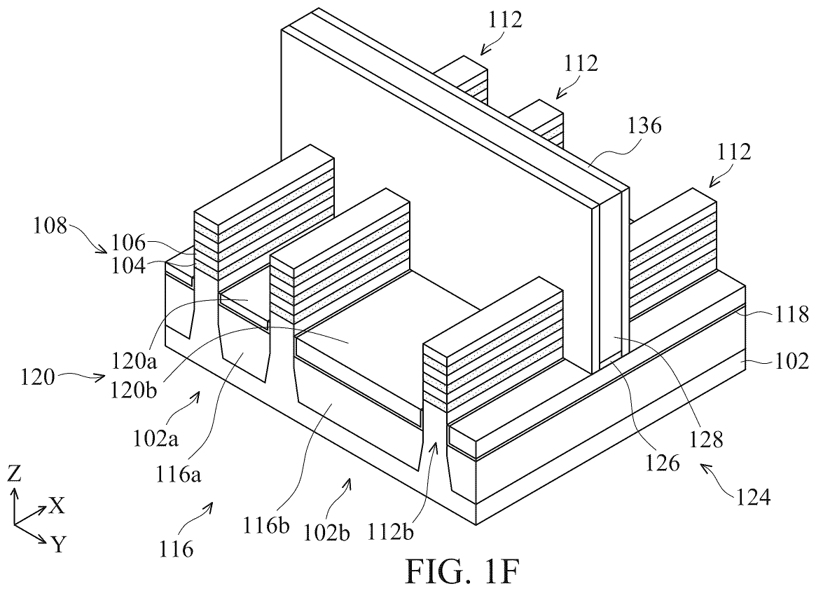

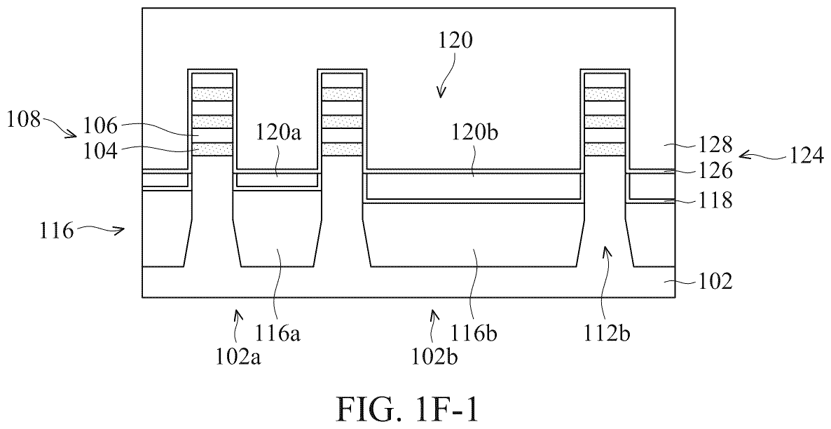

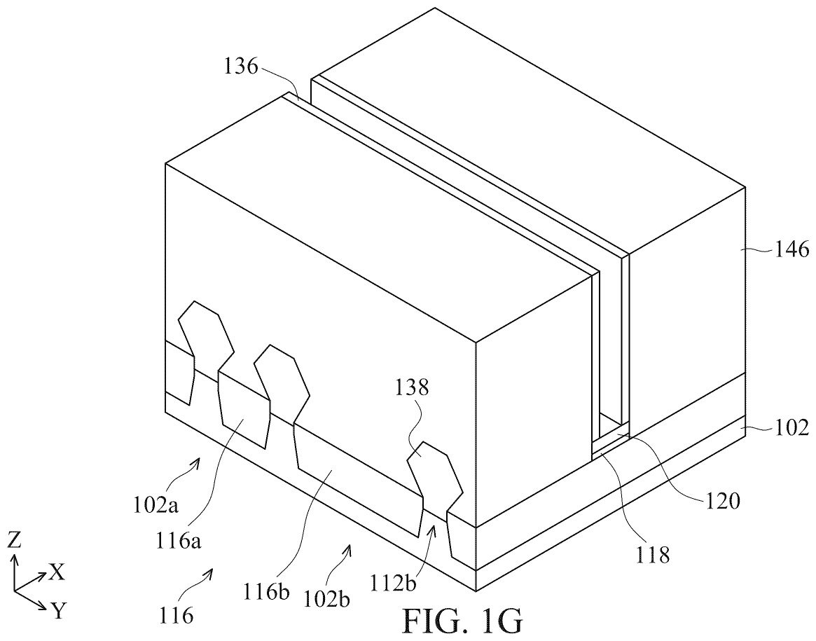

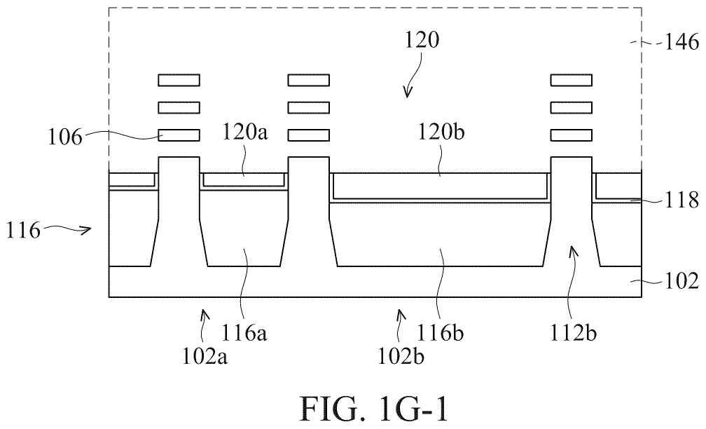

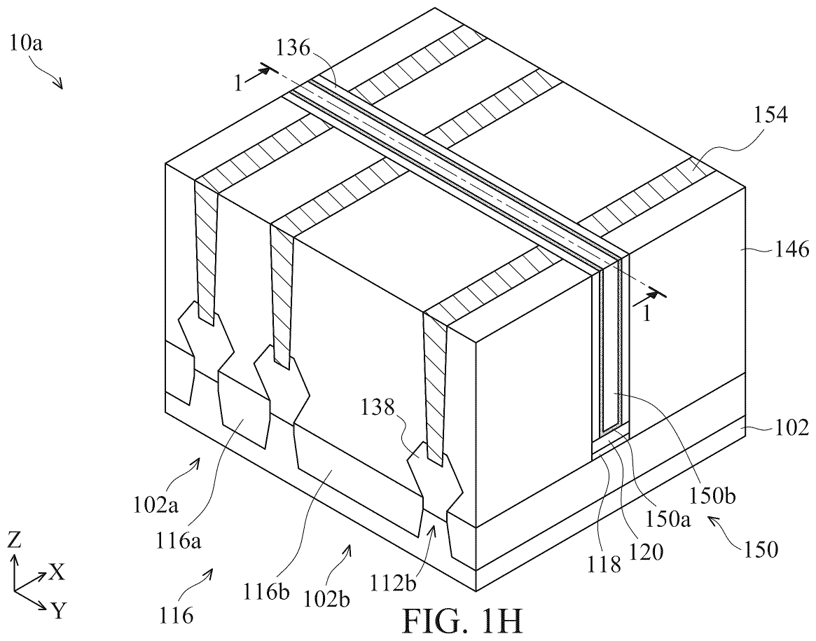

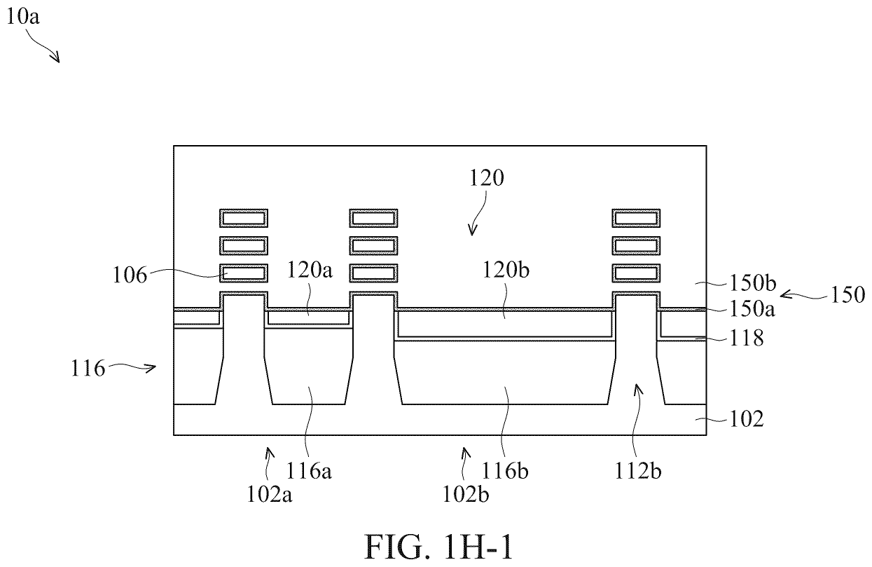

The semiconductor device structure 10a may be a nanostructure transistor. FIGS. 1A-1C, 1D, 1E, 1F, 1G, 1H are perspective representations of various stages of forming a semiconductor device structure 10a, in accordance with some embodiments of the disclosure. FIGS. 1C-1, 1D-1, 1E-1, 1F-1, 1G-1, 1H-1 are cross-sectional representations of various stages of forming a semiconductor device structure 10a, in accordance with some embodiments of the disclosure. FIGS. 1C-1, 1D-1, 1E-1, 1F-1, 1G-1, 1H-1 show cross-sectional representations taken along line 1-1 in FIG. 1H.

A semiconductor stack 108 including first semiconductor material layers 104 and second semiconductor material layers 106 are formed over a substrate 102, as shown in FIG. 1A in accordance with some embodiments. The substrate 102 may be a semiconductor wafer such as a silicon wafer. The substrate 102 may also include other elementary semiconductor materials, compound semiconductor materials, alloy semiconductor materials, or a combination thereof. Examples of the elementary semiconductor materials may include, but are not limited to, crystal silicon, polycrystalline silicon, amorphous silicon, germanium, diamond, or a combination thereof. Examples of the compound semiconductor materials may include, but are not limited to, silicon carbide, gallium nitride, gallium arsenic, gallium phosphide, indium phosphide, indium arsenide, indium antimonide, or a combination thereof. Examples of the alloy semiconductor materials may include, but are not limited to, SiGe, GaAsP, AlInAs, AlGaAs, GaInAs, GaInP, GaInAsP, or a combination thereof. The substrate 102 may include an epitaxial layer. For example, the substrate 102 may be an epitaxial layer overlying a bulk semiconductor. In addition, the substrate 102 may also be semiconductor on insulator (SOI). The SOI substrate may be fabricated by a wafer bonding process, a silicon film transfer process, a separation by implantation of oxygen (SIMOX) process, other applicable methods, or a combination thereof. The substrate 102 may be an N-type substrate. The substrate 102 may be a P-type substrate.

Next, alternating first semiconductor material layers 104 and second semiconductor material layers 106 are stacked over the substrate 102 to form the semiconductor stack 108, as shown in FIG. 1A in accordance with some embodiments. The first semiconductor material layers 104 and the second semiconductor material layers 106 may include Si, Ge, SiGe, GaAs, InSb, GaP, GaSb, InAlAs, InGaAs, GaSbP, GaAsSb, or InP. The first semiconductor material layers 104 and second semiconductor material layers 106 may be made of different materials with different etching rates. In some embodiments, the first semiconductor material layers 104 are made of SiGe and the second semiconductor material layers 106 are made of Si.

The first semiconductor material layers 104 and second semiconductor material layers 106 may be formed by low pressure chemical vapor deposition (LPCVD) process, epitaxial growth process, other applicable methods, or a combination thereof. The epitaxial growth process may include molecular beam epitaxy (MBE), metal organic chemical vapor deposition (MOCVD), or vapor phase epitaxy (VPE).

It should be noted that, although there are three layers of the first semiconductor material layers 104 and three layers of the second semiconductor material layers 106 shown in FIG. 1A, the number of the first semiconductor material layers 104 and second semiconductor material layers 106 are not limited herein, depending on the demand of performance and process. For example, the semiconductor structure may include two to five layers of the first semiconductor material layers 104 and two to five layers of the second semiconductor material layers 106.

Next, a mask structure 110 may be formed over the semiconductor stack 108. The mask structure 110 may be a multilayer structure including a pad layer and a hard mask layer formed over the pad layer. The pad layer may be made of silicon oxide, which may be formed by thermal oxidation or CVD. The hard mask layer may be made of silicon nitride, which may be formed by CVD, such as LPCVD or plasma-enhanced CVD (PECVD).

After the first semiconductor material layers 104 and the second semiconductor material layers 106 are formed as the semiconductor stack 108 over the substrate 102, the semiconductor stack 108 is patterned to form fin structures 112 using the mask structure as a mask layer, as shown in FIG. 1B in accordance with some embodiments. The fin structures 112 may include fin base structures 112b and the semiconductor stack 108, including the first semiconductor material layers 104 and the second semiconductor material layers 106, formed over the fin base structure 112b.

In some embodiments, the first distance 112da between the fin structures 112 in the first region 102a of the substrate 102 is less than the second distance 112db between the fin structures 112 in the second region 102b of the substrate 102. In some embodiments, the first distance 112da between the fin structures 112 in the first region 102a is in a range of about 25 nm to about 50 nm. In some embodiments, the second distance 112db between the fin structures 112 in the second region 102b is in a range of about 50 nm to about 100 nm. In some embodiments, the ratio of the second distance 112db to the first distance 112da is in a range of about 2 to about 4.

The patterning process may include forming the mask structure 110 over the first semiconductor material layers 104 and the second semiconductor material layers 106 and etching the semiconductor stack 108 and the underlying substrate 102 through the mask structure.

The patterning process of forming the fin structures 112 may include a photolithography process and an etching process. The photolithography process may include photoresist coating (e.g., spin-on coating), soft baking, mask aligning, exposure, post-exposure baking, developing the photoresist, rinsing and drying (e.g., hard baking). The etching process may include a dry etching process or a wet etching process.

After the fin structures 112 are formed, a liner layer may be formed over the fin structures 112 and in the trenches between the fin structures 112. The liner layer may be conformally formed over the substrate 102, the fin structures 112, and the mask structure covering the fin structures 112. A liner layer may be used to protect the fin structures 112 from being damaged in the following processes (such as an anneal process or an etching process). The liner layer may be made of silicon nitride. The liner layer may be formed using thermal oxidation, a CVD process, an atomic layer deposition (ALD) process, an LPCVD process, a plasma enhanced CVD (PECVD) process, an HDPCVD process, a flowable CVD (FCVD) process, another applicable process, or a combination thereof.

Next, an isolation material 116 is then filled into the trenches between the fin structures 112 and over the liner layer, as shown in FIGS. 1C and 1C-1 in accordance with some embodiments. The top surface of the mask structure 110 may be substantially level with the top surface of the isolation material 116 between the fin structures 112.

The isolation material 116 may be made of silicon oxide, silicon nitride, silicon oxynitride (SiON), fluoride-doped silicate glass (FSG), other low-k dielectric materials, or a combination thereof. The isolation material 116 may be deposited by a deposition process, such as a chemical vapor deposition (CVD) process (e.g. a flowable CVD (FCVD) process), a spin-on-glass process, or another applicable process.

Next, the hard mask layer of the mask structure 110 over the fin structures 112 may be removed, and the pad layer over the fin structures 112 may be exposed. The hard mask layer may be removed by performing a planarization process such as a chemical mechanical polishing (CMP) process.

Next, the isolation material 116 is etched back using an etching process, and an isolation structure 116 is formed surrounding the fin base structure 112b, as shown in FIGS. 1D and 1D-1 in accordance with some embodiments. In some embodiments, the isolation structure 116 includes a first isolation structure 116a formed surrounding the fin base structure 112b in the first region 102a, and a second isolation structure 116b is formed surrounding the fin base structure 112b in the second region 102b.

The etching process may be used to remove the top portion of the isolation material 116. The pad layer of the mask structure 110 over the fin structure 112 may be removed in the etching process. As a result, the semiconductor stack 108 may be exposed. The isolation structure 116 may be a shallow trench isolation (STI) structure 116. The isolation structure 116 may be configured to electrically isolate active regions such as fin structures 112 of the semiconductor structure 10a and prevent electrical interference and crosstalk.

In some embodiments, the isolation material 116 in the first region 102a of the substrate 102 is recessed less than the isolation material 116 in the second region 102b of the substrate 102. In some embodiments, the first isolation structure 116a is narrower and deeper than the second isolation structure 116b. In some embodiments, the top surface of the first isolation structure 116a is higher than the top surface of the second isolation structure 116b. In some embodiments, the first distance 112da between the fin structures 112 in the first region 102a is less than the second distance 112db between the fin structures 112 in the second region 102b, and the first isolation structure 116a is deeper than the second isolation structure 116b.

In some embodiments, the etching process is performed under a temperature of about 80 degree Celsius to about 140 degree Celsius. The amount of the recessed isolation material 116 may be modified by the temperature of etching process.

Next, a protection layer 118 may be formed over the fin structures 112 and the isolation structures 116a and 116b, as shown in FIGS. 1D and 1D-1 in accordance with some embodiments. The protection layer 118 may protect the fin structure 112 in the following processes. The protection layer 118 may be made of a dielectric material such as silicon oxide. The protection layer 118 may be formed by CVD, PVD, ALD, spin-on coating, or another applicable process.

Later, a hard mask layer 120 is formed over the first isolation structure 116a and the second isolation structure 116b, as shown in FIGS. 1E and 1E-1 in accordance with some embodiments. The hard mask layer 120 may be made of SiN, SiCON, SiCO, SiCN, SiON, AlN, other dielectric material with low dielectric constant (for example, dielectric constant less than 7), or a combination thereof. In some embodiments, the protection layer 118 is formed between the hard mask layer 120 and the fin structures 112. The hard mask layer 120 and the protection layer 118 may be referred to as a dielectric feature.

The hard mask layer 120 may be formed over the fin structures 112 and the isolation structures 116 first, and then the hard mask layer 120 formed over the top surfaces and the sidewalls of the fin structures 112 may be removed.

The hard mask layer 120 may include a first hard mask layer 120a in the first region 102a of the substrate 102, and a second hard mask layer 120b in the second region 102b of the substrate 102. In some embodiments, the top surface of the first hard mask layer 120a is substantially level with the top surface of the second hard mask layer 120b. The thicknesses of the first hard mask layer 120a and the second hard mask layer 120b may be different. In some embodiments, the first hard mask layer 120a is thinner than the second hard mask layer 120b. In some embodiments, the second hard mask layer 120b is shallower than the second isolation structure 116b.

In some embodiments, the top surface of the fin base structure 112b is higher than the top surface of the hard mask layer 120. In some embodiments, the fin base structure 112b has a height 112Ha over the first hard mask layer 120a in the first region 102a, and the fin base structure 112b has a height 112Hb over the second hard mask layer 120b in the second region 102b. In some embodiments, the heights 112Ha and 112Hb are substantially the same. The heights 112Ha and 112Hb may be heights of fin base structures 112b protruding from the top surface of the hard mask layers 120a and 120b, respectively. Therefore, the capacitance in the first region 102a and the second region 102b may be substantially the same, and the capacitance uniformity may be improved. In some embodiments, the heights 112Ha and 112Hb are around 20 nm. In some embodiments, the top surfaces of the fin base structure 112a and 112b have a width of around 40 nm. In some embodiments, the total depth of the first hard mask layer 120a and the first isolation structure 116a is around 65 nm.

Next, a dummy gate structure 124 is formed over and across the fin structures 112, as shown in FIGS. 1F and 1F-1 in accordance with some embodiments. In some embodiments, the dummy gate structure 124 is formed over the hard mask layer 120. The dummy gate structure 124 may be used to define the source/drain regions and the channel regions of the resulting semiconductor structure 10a. The dummy gate structure 124 may include a dummy gate dielectric layer 126 and a dummy gate electrode layer 128. The dummy gate dielectric layer 126 and the dummy gate electrode layer 128 may be replaced by the following steps to form a real gate structure with a high-k dielectric layer and a metal gate electrode layer.

The dummy gate dielectric layer 126 may include one or more dielectric materials, such as silicon oxide, silicon nitride, silicon oxynitride (SiON), HfO₂, HfZrO, HfSiO, HfTiO, HfAlO, or a combination thereof. The dummy gate dielectric layer 126 may be formed by an oxidation process (e.g., a dry oxidation process, or a wet oxidation process), a chemical vapor deposition process, other applicable processes, or a combination thereof. Alternatively, the dummy gate dielectric layer 126 may include a high-k dielectric layer (e.g., the dielectric constant is greater than 3.9) such as hafnium oxide (HfO₂). Alternatively, the high-k dielectric layer may include other high-k dielectrics, such as LaO, AlO, ZrO, TiO, Ta₂O₅, Y₂O₃, SrTiO₃, BaTiO₃, BaZrO, HfZrO, HfLaO, HfTaO, HfSiO, HfSiON, HfTiO, LaSiO, AlSiO, (Ba, Sr)TiO₃, Al₂O₃, other applicable high-k dielectric materials, or a combination thereof. The high-k dielectric layer may be formed by a chemical vapor deposition process (e.g., a plasma enhanced chemical vapor deposition (PECVD) process, or a metalorganic chemical vapor deposition (MOCVD) process), an atomic layer deposition (ALD) process (e.g., a plasma enhanced atomic layer deposition (PEALD) process), a physical vapor deposition (PVD) process (e.g., a vacuum evaporation process, or a sputtering process), other applicable processes, or a combination thereof.

The dummy gate electrode layer 128 may include polycrystalline-silicon (poly-Si), poly-crystalline silicon-germanium (poly-SiGe), other applicable materials, or a combination thereof. The dummy gate electrode layer 128 may be formed by a chemical vapor deposition process (e.g., a low pressure chemical vapor deposition process, or a plasma enhanced chemical vapor deposition process), a physical vapor deposition process (e.g., a vacuum evaporation process, or a sputtering process), other applicable processes, or a combination thereof.

A mask layer may be formed over the dummy gate structure 124. The mask layer may include multiple layers, such as an oxide layer and a nitride layer. In some embodiments, the oxide layer includes silicon oxide, and the nitride layer includes silicon nitride.

The formation of the dummy gate structure 124 may include conformally forming a dielectric material as the dummy gate dielectric layer 126. Afterwards, a conductive material may be formed over the dielectric material as the dummy gate electrode layer 128. The mask layer, including the oxide layer and the nitride layer, may be formed over the conductive material. Next, the dielectric material and the conductive material may be patterned and etched through the mask layer to form the dummy gate structure 124, as shown in FIGS. 1F and 1F-1 in accordance with some embodiments. The dummy gate dielectric layer 126 and the dummy gate electrode layer 128 may be etched by a dry etching process. After the etching process, the first semiconductor material layers 104 and the second semiconductor material layers 106 may be exposed at opposite sides of the dummy gate structure 124.

Next, a conformal dielectric layer is formed over the substrate 102 and the dummy gate structure 124, and then an etching process is performed. A pair of gate spacer layers 136 is formed over opposite sidewalls of the dummy gate structure 124, as shown in FIG. 1F in accordance with some embodiments

The gate spacer layers 136 may be multi-layer structures formed by different materials with different etching selectivity. The gate spacer layers 136 may be made of silicon oxide, silicon nitride, silicon oxynitride, dielectric materials, or a combination thereof. The gate spacer layers 136 may be formed by a chemical vapor deposition (CVD) process, a spin-on-glass process, or another applicable process.

After the gate spacer layers 136 are formed, the first semiconductor material layers 104 and the second semiconductor material layers 106 of the fin structures 112 not covered by the dummy gate structure 124 and the gate spacer layers 136 may be etched to form the source/drain opening beside the dummy gate structure 124. A recess may be formed in the isolation structure 116 when etching the first semiconductor material layers 104 and the second semiconductor material layers 106 of the fin structures 112. The hard mark layer 120 and the protection layer 118 not covered by the dummy gate structure 124 and the gate spacer layers 136 may be consumed during the etching process.

The fin structures 112 may be recessed by performing a number of etching processes. That is, the first semiconductor material layers 104 and the second semiconductor material layers 106 of the fin structures 112 may be etched in different etching processes. The etching process may be a dry etching process or a wet etching process. The fin structures 112 may be etched by a dry etching process.

Next, the first semiconductor material layers 104 may be laterally etched from the source/drain opening to form recesses. The outer portions of the first semiconductor material layers 104 may be removed, and the inner portions of the first semiconductor material layers 104 under the dummy gate structure 124 and the gate spacer layers 136 may remain. After the lateral etching process, the sidewalls of the etched first semiconductor material layers 104 may be not aligned with the sidewalls of the second semiconductor material layers 106.

The lateral etching of the first semiconductor material layers 104 may be a dry etching process, a wet etching process, or a combination thereof. In some embodiments, the first semiconductor material layers 104 are Ge or SiGe and the second semiconductor material layers 106 are Si, and the first semiconductor material layers 104 are selectively etched to form the recesses by using a wet etchant such as, but not limited to, ammonium hydroxide (NH₄OH), tetramethylammonium hydroxide (TMAH), ethylenediamine pyrocatechol (EDP), or potassium hydroxide (KOH) solutions, or the like.

Next, an inner spacer may be formed in the recess. The inner spacer may provide a barrier between subsequently formed source/drain epitaxial structures and gate structure. The inner spacer may be made of a dielectric material such as silicon oxide (SiO₂), silicon nitride (SiN), silicon carbide (SiC), silicon oxynitride (SiON), silicon carbon nitride (SiCN), silicon oxide carbonitride (SiOCN), or a combination thereof. The inner spacer may be formed using a deposition process. The deposition process may include a CVD process (such as LPCVD, PECVD, SACVD, or FCVD), an ALD process, another applicable method, or a combination thereof.

Next, a source/drain epitaxial structure 138 is formed in the source/drain opening, as shown in FIG. 1G in accordance with some embodiments. The source/drain epitaxial structure 138 may be formed over opposite sides of the dummy gate structure 124. The source/drain epitaxial structure 138 may refer to a source or a drain, individually or collectively dependent upon the context.

A strained material may be grown in the source/drain opening using an epitaxial (epi) process to form the source/drain epitaxial structure 138. In addition, the lattice constant of the strained material may be different from the lattice constant of the substrate 102. The source/drain epitaxial structure 138 may include SiGeB, SiP, SiAs, SiGe, other applicable materials, or a combination thereof. The source/drain epitaxial structure 138 may be formed by an epitaxial growth step, such as metalorganic chemical vapor deposition (MOCVD), metalorganic vapor phase epitaxy (MOVPE), plasma-enhanced chemical vapor deposition (PECVD), remote plasma-enhanced chemical vapor deposition (RP-CVD), molecular beam epitaxy (MBE), hydride vapor phase epitaxy (HVPE), liquid phase epitaxy (LPE), chloride vapor phase epitaxy (Cl-VPE), or any other suitable method.

The source/drain epitaxial structure 138 may be in-situ doped during the epitaxial growth process. For example, the source/drain epitaxial structure 138 may be the epitaxially grown SiGe doped with boron (B). For example, the source/drain epitaxial structure 138 may be the epitaxially grown Si doped with carbon to form silicon:carbon (Si:C) source/drain features, phosphorous to form silicon:phosphor (Si:P) source/drain features, or both carbon and phosphorous to form silicon carbon phosphor (SiCP) source/drain features. The source/drain epitaxial structure 138 may be doped in one or more implantation processes after the epitaxial growth process.

Next, an etch stop layer may be formed over the source/drain epitaxial structure 138. More specifically, the etch stop layer may cover the sidewalls of the gate spacer layers 136 and the top surface of the source/drain epitaxial structure 138. The etch stop layer may be made of a dielectric material such as silicon nitride, silicon oxide, silicon oxynitride (SiON), other applicable materials, or a combination thereof. The etch stop layer may be formed by a chemical vapor deposition process (e.g., a plasma enhanced chemical vapor deposition (PECVD) process, or a metalorganic chemical vapor deposition (MOCVD) process), an atomic layer deposition (ALD) process (e.g., a plasma enhanced atomic layer deposition (PEALD) process), a physical vapor deposition (PVD) process (e.g., a vacuum evaporation process, or a sputtering process), other applicable processes, or a combination thereof.

After the etch stop layer is formed, an inter-layer dielectric (ILD) structure 146 is formed over the etch stop layer and the source/drain epitaxial structure 138, as shown in FIGS. 1G and 1G-1 in accordance with some embodiments. In some embodiments, the ILD structure 146 surrounds the source/drain epitaxial structure 138.

The ILD structure 146 may include multilayers made of multiple dielectric materials, such as silicon oxide (SiOₓ, where x may be a positive integer), silicon oxycarbide (SiCO_{y}, where y may be a positive integer), silicon oxycarbonitride (SiNCO_{z}, where z may be a positive integer), silicon nitride, silicon oxynitride, phosphosilicate glass (PSG), borophosphosilicate glass (BPSG), low-k dielectric material, or another applicable dielectric material. Examples of low-k dielectric materials include, but are not limited to, fluorinated silica glass (FSG), carbon doped silicon oxide, amorphous fluorinated carbon, parylene, bis-benzocyclobutenes (BCB), or polyimide. The ILD structure 146 may be formed by chemical vapor deposition (CVD), physical vapor deposition (PVD), atomic layer deposition (ALD), spin-on coating, or another applicable process.

Afterwards, a planarizing process or an etch-back process may be performed on the ILD structure 146 until the top surface of the dummy gate structure 124 is exposed. After the planarizing process, the top surface of the dummy gate structure 124 may be substantially level with the top surfaces of the gate spacer layers 136 and the ILD structure 146. The planarizing process may include a grinding process, a chemical mechanical polishing (CMP) process, an etching process, other applicable processes, or a combination thereof.

Next, the first semiconductor material layers 104 may be removed and gaps may be formed between the second semiconductor material layers 106. More specifically, the second semiconductor material layers 106 exposed by the gaps form nanostructures 106, and the nanostructures 106 are configured to function as channel regions 106 in the resulting semiconductor devices 10a in accordance with some embodiments. In some embodiments, the nanostructures 106 and the fin structures 112 are referred to as channel structures.

In some embodiments, the height difference between the top surface of the topmost nanostructures 106 in the second region 102b and the top surface of the second isolation structure 116b is greater than the height difference between the top surface of the topmost nanostructures 106 in the first region 102a and the top surface of the first isolation structure 116a.

The first semiconductor material layers 104 may be removed by performing one or more etching processes. The etching process may include a selective wet etching process, such as APM (e.g., ammonia hydroxide-hydrogen peroxide-water mixture) etching process. The wet etching process uses etchants such as ammonium hydroxide (NH₄OH), TMAH, ethylenediamine pyrocatechol (EDP), potassium hydroxide (KOH) solutions, or a combination thereof.

It should be noted that, the ILD structure 146 is invisible in FIG. 1G-1. The ILD structure 146 is shown in dashed line to indicate the position of the ILD structure 146.

Next, gate structures 150 are formed surrounding the nanostructures 106 and over the nanostructures 106, as shown in FIGS. 1H and 1H-1 in accordance with some embodiments. Gate structures 150 are formed surrounding the nanostructures 106 to form gate-all-around (GAA) transistor structures. Therefore, the gate control ability may be enhanced.

In some embodiments as shown in FIGS. 1H and 1H-1, the gate structures 150 are multi-layered structures. Each of the gate structures 150 may include an interfacial layer, a gate dielectric layer 150a, a work function layer 150b, and a gate electrode layer.

In some embodiments, the gate structure 150 covers top surfaces and sidewalls of the fin base structures 112b in the first region 102a and the second region 102b. In some embodiments, the hard mask layer 120 is formed between the isolation structures 116 and the gate structure 150.

The interfacial layer may be formed around the nanostructures 106 and on the exposed portions of the fin base structures 112b. The interfacial layer may be made of silicon oxide, and the interfacial layer may be formed by thermal oxidation.

The gate dielectric layer 150a may be formed over the interfacial layer, so that the nanostructures 106 are surrounded (e.g. wrapped) by the gate dielectric layer 150a. In addition, the gate dielectric layer 150a also covers the sidewalls of the gate spacer layers 136 and the inner spacers in accordance with some embodiments. The gate dielectric layer 150a may be made of one or more layers of dielectric materials, such as HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other applicable high-k dielectric materials, or a combination thereof. The gate dielectric layer 150a may be formed using CVD, ALD, other applicable methods, or a combination thereof.

The work function layers 150b may be conformally formed over the nanostructure 106. The work function layers 150b may be multi-layer structures. The work function layers 150b may be made of a metal material. The metal material of the work function layers 150b may include an N-work-function metal. The N-work-function metal may include tungsten (W), copper (Cu), titanium (Ti), silver (Ag), aluminum (Al), titanium aluminum alloy (TiAl), titanium aluminum nitride (TiAlN), tantalum carbide (TaC), tantalum carbon nitride (TaCN), tantalum silicon nitride (TaSiN), manganese (Mn), zirconium (Zr), or a combination thereof. The metal material of the work function layer 150b may include a P-work-function metal. The P-work-function metal may include titanium nitride (TiN), tungsten nitride (WN), tantalum nitride (TaN), ruthenium (Ru) or a combination thereof. The work function layers 150b may be formed by using CVD, ALD, other applicable methods, or a combination thereof.

Next, a gate electrode layer may be formed over the work function layer 150b. The gate electrode layer may be made of one or more layers of conductive material, such as aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, another suitable material, or a combination thereof. The gate electrode layer may be formed using CVD, ALD, electroplating, another applicable method, or a combination thereof. After the gate electrode layer is formed, a planarization process such as CMP or an etch-back process may be performed.

Next, an opening is formed in the ILD structure 146, and a metal semiconductor compound layer may be formed over the source/drain epitaxial structure 138. The metal semiconductor compound layer may reduce the contact resistance between the source/drain epitaxial structure 138 and the subsequently formed contact structure over the source/drain epitaxial structure 138. The metal semiconductor compound layer may be made of titanium silicide (TiSi₂), nickel silicide (NiSi), cobalt silicide (CoSi), or other suitable low-resistance materials. The metal semiconductor compound layer may be formed over the source/drain epitaxial structure 138 by forming a metal layer over the source/drain epitaxial structure 138 first. The metal layer may react with the source/drain epitaxial structure 138 in an annealing process and a metal semiconductor compound layer may be produced. Afterwards, the unreacted metal layer may be removed in an etching process and the metal semiconductor compound layer may be left.

Next, a barrier layer may be conformally formed over the bottom surface and the sidewalls of the opening. Afterwards, the barrier layer may be etched back. The barrier layer remains over the bottom surface of the opening. The barrier layer may be formed before filling the conductive material in the opening to prevent the conductive material from diffusing out. The barrier layer may also serve as an adhesive or glue layer. The material of the barrier layer may be TiN, Ti, other applicable materials, or a combination thereof. The barrier layer may be formed by depositing the barrier layer materials by a physical vapor deposition process (PVD) (e.g., evaporation or sputtering), an atomic layer deposition process (ALD), an electroplating process, other applicable processes, or a combination thereof.

Afterwards, a contact structure 154 may be formed into the opening over the source/drain epitaxial structure 138, as shown in FIG. 1H in accordance with some embodiments. The contact structure 154 may be made of a metal material (e.g., Co, Ni, W, Ti, Ta, Cu, Al, Ru, Mo, TiN, TaN, and/or a combination thereof), metal alloys, poly-Si, other applicable conductive materials, or a combination thereof. The contact structure 154 may be formed by a chemical vapor deposition process (CVD), a physical vapor deposition process (PVD), (e.g., evaporation or sputter), an atomic layer deposition process (ALD), an electroplating process, another suitable process, or a combination thereof to deposit the conductive materials of the contact structure 154, and then a planarization process such as a chemical mechanical polishing (CMP) process or an etch back process is optionally performed to remove excess conductive materials. After the planarization process, the top surface of the contact structure 154 may be level with the top surface of the spacer layers 132. In some embodiments, the contact structure 154 formed over adjacent source/drain epitaxial structures 136 are separated from each other.

By forming thicker second hard mask layer 120b over wider and thinner second isolation structures 116b, the heights of the fin base structures 112b in the first region 102a and the second region 102b over the hard mask layers 120 may be substantially the same. Therefore, the loading effect may be compensated and the capacitance uniformity may be improved.

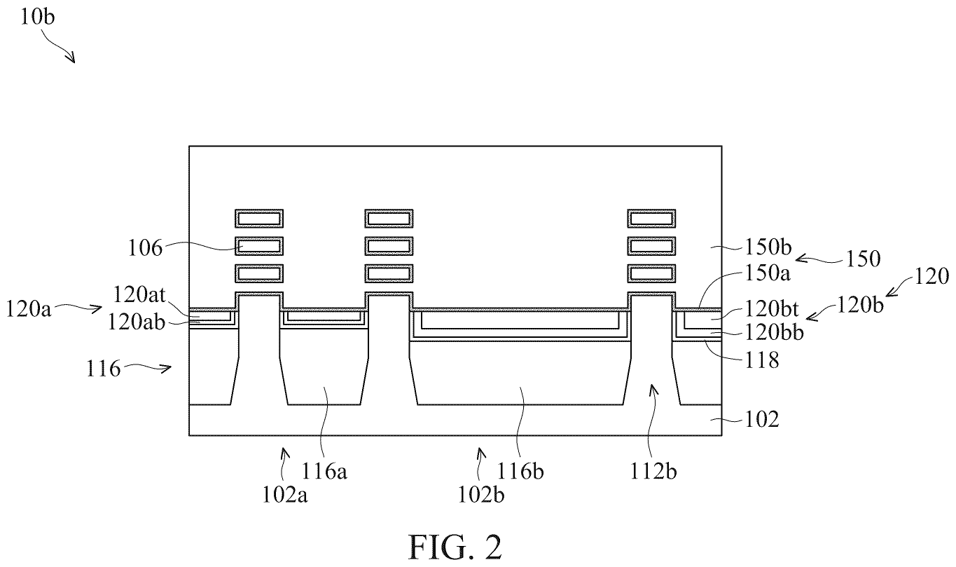

Many variations and/or modifications may be made to the embodiments of the disclosure. FIG. 2 is a cross-sectional representation of a semiconductor device structure 10b. Some processes or devices are the same as, or similar to, those described in the embodiments above, and therefore the descriptions of these processes and devices are not repeated herein. The difference from the embodiments described above is that, as shown in FIG. 2 in accordance with some embodiments, multiple hard mask layers 120a and 120b are formed over the isolation structures 116a and 116b, respectively.

A bottom hard mask layer 120ab and 120bb may be conformally formed over the isolation structures 116 and the fin structures 112 first, and a top hard mask layer 120at and 120bt may be formed over the bottom hard mask layer 120ab and 120bb, as shown in FIG. 2 in accordance with some embodiments. In some embodiments, the hard mask layers 120ab and 120at are formed in the first region 102a of the substrate 102, and the hard mask layers 120bb and 120bt are formed in the second region 102b of the substrate 102. Later, the hard mask layers 120ab, 120bb, 120at, and 120bt formed over the top surfaces and the sidewalls of the fin structures 112 may be removed.

In some embodiments, the bottom hard mask layer 120ab and 120bb are made of the same material and are formed in the same deposition process. In some embodiments, the top hard mask layer 120at and 120bt are made of the same material and are formed in the same deposition process.

The bottom hard mask layer 120ab and 120bb and the top hard mask layers 120at and 120bt may be made of SiN, SiCON, SiCO, SiCN, SiON, AlN, other dielectric material with low dielectric constant (for example, dielectric constant less than 7), or a combination thereof. In some embodiments, the hardness of the top hard mask layers 120at and 120bt is greater than the bottom hard mask layer 120ab and 120bb so that the hard mask layers 120a and 120b are more etching resistant in the following etching processes. In some embodiments, the dielectric constant of the bottom hard mask layer 120ab and 120bb is less than the dielectric constant of the top hard mask layers 120at and 120bt. Therefore, the capacitance may be reduced.

The thickness of the hard mask layers 120bt and 120bb in the second region 102b of the substrate 102 may be different from the thickness of the hard mask layers 120at and 120ab in the first region 102a of the substrate 102. In some embodiments, the bottom hard mask layer 120bb in the second region 102b is thicker than the bottom hard mask layer 120ab in the first region 102a.

It should be noted that, although there are two layers of the bottom hard mask layer 120ab and 120bb and the top hard mask layers 120at and 120bt shown in FIG. 2, the number of the hard mask layers 120 are not limited herein, depending on the demand of performance and process.

By forming thicker second hard mask layer 120b over wider and thinner second isolation structures 116b, the heights of the fin base structures 112b in the first region 102a and the second region 102b over the hard mask layers 120 may be substantially the same. Therefore, the loading effect may be compensated and the capacitance uniformity may be improved. The hard mask layers 120a and 120b may be multiple hard mask layers, and the second hard mask layers 120bt and 120bb in the second region 102b may be thicker than the first hard mask layers 102at and 120ab in the first region 102a, respectively.

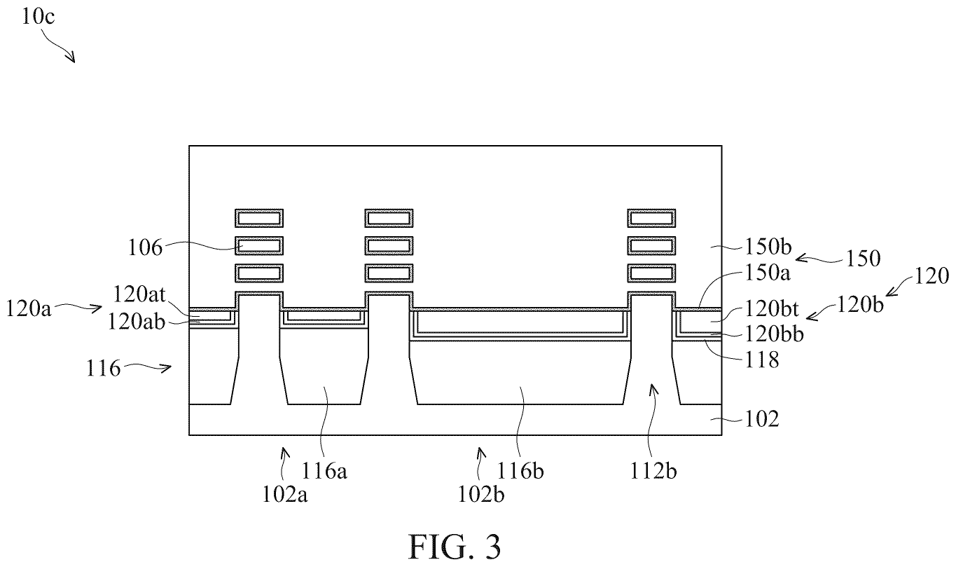

Many variations and/or modifications may be made to the embodiments of the disclosure. FIG. 3 is a cross-sectional representation of a semiconductor device structure 10c. Some processes or devices are the same as, or similar to, those described in the embodiments above, and therefore the descriptions of these processes and devices are not repeated herein. The difference from the embodiments described above is that, as shown in FIG. 3 in accordance with some embodiments, the thicknesses of the bottom hard mask layer 120bb and 120ab are substantially the same.

The bottom hard mask layer 120bb and 120ab and the top hard mask layer 120bt and 120at may be formed by different materials and different processes. In some embodiments, the thicknesses of the bottom hard mask layer 120bb and 120ab are substantially the same, and the thicknesses of the top hard mask layer 120bt in the second region 102b of the substrate 102 is thicker than the top hard mask layer 120at in the first region 102a of the substrate 102. In some embodiments, the top hard mask layer 120bt is thicker than the bottom hard mask layer 120bb in the second region 102b. In some embodiments, the top surface of the top hard mask layer 120at in the first region 102a may be substantially level with the top surface of the top hard mask layer 102bt in the second region 102b. Therefore, the capacitance may be substantially the same.

By forming thicker second hard mask layer 120b over wider and thinner second isolation structures 116b, the heights of the fin base structures 112b in the first region 102a and the second region 102b over the hard mask layers 120 may be substantially the same. Therefore, the loading effect may be compensated and the capacitance uniformity may be improved. The hard mask layer 120a and 120b may be multiple hard mask layers. The thicknesses of the bottom hard mask layer 120bb and 120ab are substantially the same, and the top surface of the hard mask layers 120a and 120b may be substantially at the same level.

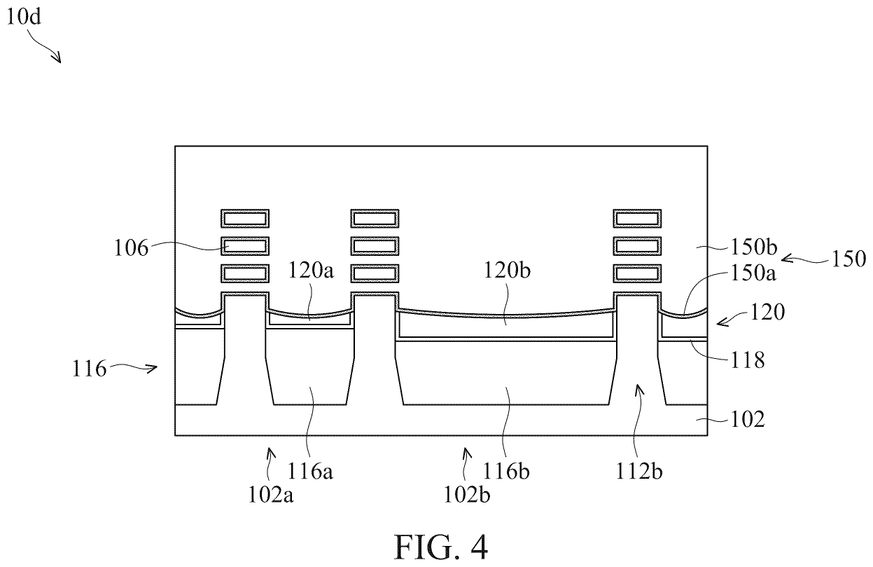

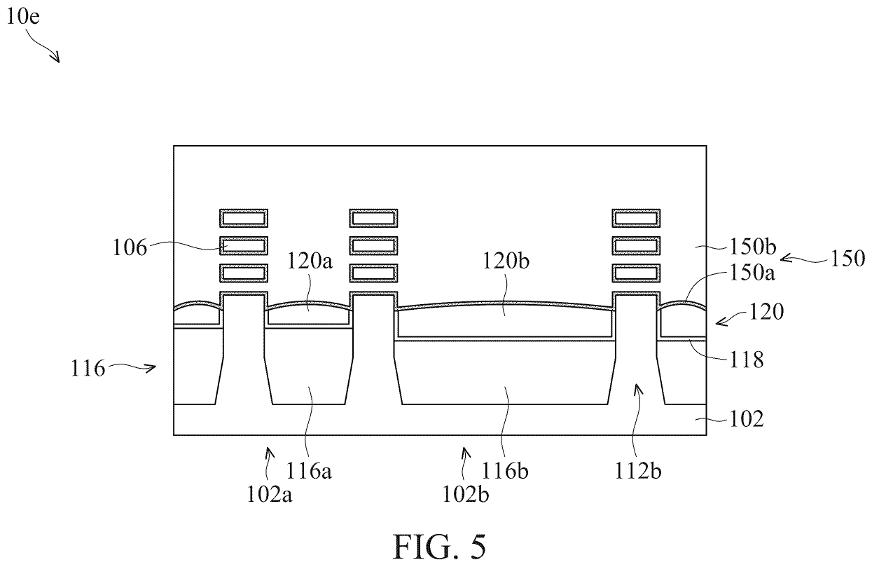

Many variations and/or modifications may be made to the embodiments of the disclosure. FIGS. 4 and 5 are a cross-sectional representation of a semiconductor device structure 10d and 10e. Some processes or devices are the same as, or similar to, those described in the embodiments above, and therefore the descriptions of these processes and devices are not repeated herein. The difference from the embodiments described above is that, as shown in FIGS. 4 and 5 in accordance with some embodiments, the top surface of the hard mask layer 120 may be curved.

The hard mask layer 120 has a concave top surface, as shown in FIG. 4 in accordance with some embodiments. The hard mask layer 120 has a convex top surface, as shown in FIG. 5 in accordance with some embodiments. During the etching back process of the hard mask layer 120, the etching rate of the hard mask layer 120 in the middle portion and the end portion may be different due to the protection layer 118 formed over the sidewalls of the fin structure 112. Therefore, the thicknesses of the middle portion and the end portion of the hard mask layer 120 may be different. In some embodiments, the middle portion of the hard mask layer 120 is thicker than the end portion of the hard mask layer 120, as shown in FIG. 5 in accordance with some embodiments.

By forming thicker second hard mask layer 120b over wider and thinner second isolation structures 116b, the heights of the fin base structures 112b in the first region 102a and the second region 102b over the hard mask layers 120 may be substantially the same. Therefore, the loading effect may be compensated and the capacitance uniformity may be improved. The hard mask layer 120 may have a concave or a convex top surface.

As described previously, in the second region 102b with greater distance 112db between the fin structures 112, the second isolation structure 116b may be wider and thinner than the first isolation structure 116a in the first region 102a. The hard mask layer 120b formed over the second isolation structure 116b may be thicker, and the top surface of the second hard mask layer 120b may be substantially level with the top surface of the first hard mask layer 120a formed in the first region 102a. The fin base structure 112b may have the same height over the hard mask layers 120a and 120b, and the capacitance uniformity may be improved. In some embodiments as shown in FIG. 2, the hard mask layer 120 is a multiple-layer structure, and each of the hard mask layers 120b in the second region 102b is thicker than the corresponding layer of the hard mask layers 120a in the first region 102a. In some embodiments as shown in FIG. 3, the hard mask layer 120 is a multiple-layer structure, and the bottom hard mask layers 120ab and 120bb have substantially the same thickness. In some embodiments as shown in FIG. 4, the hard mask layer 120 has a concave top surface. In some embodiments as shown in FIG. 5, the middle portion of the hard mask layer 120 is thicker than the end portions of the hard mask layer 120.

Embodiments of a semiconductor device structure and a method for forming the same are provided. In the region with greater distance between the fin structures, the isolation structure may be thinner, and the hard mask layer over the isolation structure may be thicker. The fin base structure may have the same height over the hard mask layer, and the uniformity of the capacitance may be improved.

In some embodiments, a method for forming a semiconductor device structure is provided. The method for forming a semiconductor device structure includes forming fin base structures over a first region and a second region of a substrate and channel layers over the fin base structures. The distances between the fin structures in the first region and the second region are different. The method for forming a semiconductor device structure also includes filling an isolation material between the fin base structures. The method for forming a semiconductor device structure also includes recessing the isolation material to form a first isolation structure between the fin base structures in the first region and a second isolation structure between the fin base structures in the second region. The method for forming a semiconductor device structure also includes depositing a hard mask layer over the first isolation structure and the second isolation structure. The method for forming a semiconductor device structure also includes forming a gate structure wrapped around the channel layers. The thicknesses of the hard mask layer in the first region and the second region are different, and the top surface of the hard mask layer in the first region is substantially level with the top surface of the hard mask layer in the second region.

In some embodiments, a method for forming a semiconductor device structure is provided. The method for forming a semiconductor device structure includes forming fin structures with a stack of alternating first semiconductor layers and second semiconductor layers in a first region and a second region over a substrate. The method for forming a semiconductor device structure also includes forming a first isolation structure between the fin structures in the first region and a second isolation structure between the fin structures in the second region. The method for forming a semiconductor device structure also includes depositing a first hard mask layer over the first isolation structure and the second isolation structure. The method for forming a semiconductor device structure also includes removing the first semiconductor layers to form an opening between the second semiconductor layers. The method for forming a semiconductor device structure also includes forming a gate structure wrapped around the second semiconductor layers. The first distance between the fin structures in the first region is less than the second distance between the fin structures in the second region, and the top surface of the first isolation structure is higher than the top surface of the second isolation structure.

In some embodiments, a semiconductor device structure is provided. The semiconductor device structure includes nanostructures formed over fin structures over a first region and a second region of a substrate. The semiconductor device structure also includes a first isolation structure formed between the fin structures in the first region. The semiconductor device structure also includes a second isolation structure formed between the fin structures in the second region. The semiconductor device structure also includes a hard mask layer formed over the first isolation structure and the second isolation structure. The semiconductor device structure also includes a gate structure wrapped around the nanostructures. The first isolation structure is narrower than the second isolation structure, and the first isolation structure is thicker than the second isolation structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor device structure, comprising:
forming fin base structures over a first region and a second region of a substrate and channel layers over the fin base structures, wherein distances between the fin structures in the first region and the second region are different;
filling an isolation material between the fin base structures;
recessing the isolation material to form a first isolation structure between the fin base structures in the first region and a second isolation structure between the fin base structures in the second region;
depositing a hard mask layer over the first isolation structure and the second isolation structure; and
forming a gate structure wrapped around the channel layers,
wherein thicknesses of the hard mask layer in the first region and the second region are different, and a top surface of the hard mask layer in the first region is substantially level with a top surface of the hard mask layer in the second region.

2. The method for forming the semiconductor device structure as claimed in claim 1, wherein a first distance between the fin structures in the first region is less than a second distance between the fin structures in the second region, and the hard mask layer in the first region is thinner than the hard mask layer in the second region.

3. The method for forming the semiconductor device structure as claimed in claim 1, wherein the isolation material in the first region is recessed less than the isolation material in the second region.

4. The method for forming the semiconductor device structure as claimed in claim 1, further comprising;
forming a mask structure over the fin structures;
removing the mask structure when recessing the isolation material.

5. The method for forming the semiconductor device structure as claimed in claim 4, wherein a top surface of the mask structure is substantially level with a top surface of the isolation material between the fin structures.

6. The method for forming the semiconductor device structure as claimed in claim 1, further comprising:
forming a protection layer over the fin structures, the first isolation structure, and the second isolation structure before depositing the hard mask layer.

7. The method for forming the semiconductor device structure as claimed in claim 1, wherein a top surface of fin base structures is higher than a top surface of the hard mask layer.

8. A method for forming a semiconductor device structure, comprising:
forming fin structures with alternating stacked first semiconductor layers and second semiconductor layers in a first region and a second region over a substrate;
forming a first isolation structure between the fin structures in the first region and a second isolation structure between the fin structures in the second region;
depositing a first hard mask layer over the first isolation structure and the second isolation structure;
removing the first semiconductor layers to form an opening between the second semiconductor layers; and
forming a gate structure wrapped around the second semiconductor layers,
wherein a first distance between the fin structures in the first region is less than a second distance between the fin structures in the second region, and a top surface of the first isolation structure is higher than a top surface of the second isolation structure.

9. The method for forming the semiconductor device structure as claimed in claim 8, wherein the gate structure covers top surfaces and sidewalls of base portions of the fin structures in the first region and the second region.

10. The method for forming the semiconductor device structure as claimed in claim 8, further comprising;
forming a dummy gate structure over the fin structures and the first hard mask layer; and
removing the dummy gate structure before removing the first semiconductor layers.

11. The method for forming the semiconductor device structure as claimed in claim 8, further comprising:
depositing a second hard mask layer over the first hard mask layer.

12. The method for forming the semiconductor device structure as claimed in claim 11, wherein the second hard mask layer is thicker than the first hard mask layer in the second region.

13. The method for forming the semiconductor device structure as claimed in claim 11, wherein the first hard mask layer in the second region is thicker than the first hard mask layer in the first region.

14. A semiconductor device structure, comprising:
first channel structures, second channel structures, and third channel structures over a substrate;
a first isolation structure formed between the first channel structures and the second channel structures;
a second isolation structure formed between the second channel structures and the third channel structures;
a first dielectric feature and a second dielectric feature formed over the first isolation structure and the second isolation structure, respectively; and
a gate structure wrapped around the first channel structures, the second channel structures, and the third channel structures;
wherein a first distance between the first channel structures and the second channel structures is less than a second distance between the second channel structures and the third channel structures, and the first isolation structure is deeper than the second isolation structure.

15. The semiconductor device structure as claimed in claim 14, wherein the first dielectric feature and the second dielectric feature have different depths.

16. The semiconductor device structure as claimed in claim 14, the first dielectric feature is shallower than the second dielectric feature, and the second dielectric feature is shallower than the second isolation structure.

17. The semiconductor device structure as claimed in claim 14, wherein the first dielectric feature and the second dielectric feature have concave top surfaces.

18. The semiconductor device structure as claimed in claim 14, wherein middle portions of the first dielectric feature and the second dielectric feature are thicker than end portions of the first dielectric feature and the second dielectric feature.

19. The semiconductor device structure as claimed in claim 14, wherein the first dielectric feature is formed between the first isolation structure and the gate structure.

20. The semiconductor device structure as claimed in claim 14, further comprising:
a protection layer formed between the first dielectric feature and the first channel structures.
